(19) United States
(12) Patent Application Publication
(10) Pub. No.: US 2016/0380095 A1
(43) Pub. Date: Dec. 29, 2016

(54) HIGH VOLTAGE FINFET STRUCTURE WITH SHAPED DRIFT REGION

(71) Applicant: International Business Machines Corporation, Armonk, NY (US)

(72) Inventors: Lyndon R. Logan, Poughkeepsie, NY (US); Edward J. Nowak, Essex Junction, VT (US); Robert R. Robison, Colchester, VT (US)

(21) Appl. No.: 14/750,476

(22) Filed: Jun. 25, 2015

(51) Int. Cl. H01L 29/78; H01L 29/08; H01L 29/10; H01L 29/66

(52) U.S. Cl. CPC H01L 29/785; H01L 29/7835; H01L 29/66803; H01L 29/0886; H01L 29/1045; H01L 29/7816; H01L 29/66681

(57) ABSTRACT

Devices and methods for a high voltage FinFET with a shaped drift region include a lateral diffusion metal oxide semiconductor (LDMOS) FinFET having a substrate with a top surface and a fin attached to the top surface. This fin includes a source region having a first type of doping, an undoped gate-control region adjacent the source region, a drift region adjacent the undoped gate-control region opposite the source region, and a drain region. The amount of doping of the source region is greater than the amount in the drift region. The drain region has the same type of doping and is adjacent the drift region. The fin in the drift region is tapered, being wider closest to the undoped gate-control region and thinner closest to the drain region. A gate stack is attached to the top surface of the substrate and located with the undoped gate-control region.

### BACKGROUND

The present disclosure relates to semiconductors and, more particularly, to structures and methods for forming field-isolated bulk fin field effect transistor (FinFET).

Lateral diffusion metal oxide semiconductor (LDMOS) transistors provide high value for high-voltage/high-power switches and RF output stages. Doping is challenging to control, however, in the lightly doped drift region of a narrow fin for the LDMOS design.

### SUMMARY

The asymmetric shaped drift region, because of its shape, drops most of the voltage away from the gate. The field, closer to the gate, becomes more graded. By grading the field, hot electron effect is reduced. The asymmetric drift region also concentrates more of the self-heating from voltage drop ‘away’ from the gate, near to the drain, where it can be more effectively cooled. In other words, specific fin geometry shaping may be used to lower the peak electric fields in the drift region at the drain of FinFET LDMOS devices.

Systems herein include a lateral diffusion metal oxide semiconductor (LDMOS) FinFET, which has a substrate having a top surface with a fin attached to the top surface. This fin includes multiple regions such as: a source region having doping of a first polarity, an undoped gate-control region adjacent to the source region, a drift region adjacent to the undoped gate-control region, and a drain region. The undoped gate-control region is between the source region and the drift region and the drift region is between the undoped gate-control region and the drain region. The drift region has doping of the first polarity. The amount of doping of the source region is greater than the amount of doping of the drift region. The drain region is next to the drift region and the drain region has doping of the first polarity. The drift region comprises a fin, tapered in geometry, being wider closest to the undoped gate-control region and thinner closest to the drain region. The systems also include a gate stack attached to the top surface of the substrate and located on at least two sides of the undoped gate-control region.

The devices and methods also include a device, comprising a semiconductor substrate. This semiconductor substrate has a trench isolation structure in the top surface of the substrate and a fin structure. This fin structure is perpendicular to the semiconductor substrate and bound by the trench isolation structure. The fin structure comprises, a source region having a first type of doping, an undoped gate-control region adjacent to the source region, a drift region adjacent to the undoped gate-control region, and a drain region adjacent to the drift region. The undoped gate-control region is between the source region and the drift region and the drift region is between the undoped gate-control region and the drain region. The drift region has the first type of doping, with the source region being more heavily doped relative to the drift region. The drift region is wider closer to the undoped gate-control region and thinner closer to the drain region. The drain region also has the first type of doping. The devices and methods include a gate conductor over the substrate, relative to the top surface. This gate conductor is adjacent to the undoped gate-control region.

According to exemplary methods herein, a substrate of semiconductor material is provided, with the substrate having a top surface. A fin is formed on the substrate. This fin has a height above the top surface of the substrate. According to the method, a first portion of the fin is doped with a first type of doping. The first portion of the fin comprises a source region. A gate conductor is formed on the substrate. The gate conductor is formed around an undoped gate-control portion of the fin adjacent to the source region. A drift region is formed in the fin adjacent to the undoped gate-control portion of the fin. The undoped gate-control portion of the fin is between the source region and the drift region. The drift region has the first type of doping, the source region being more heavily doped relative to the drift region. A second portion of the fin adjacent to the drift region is doped with the first type of doping. The second portion of the fin comprises a drain region. The drift region is between the undoped gate-control portion of the fin and the drain region. The source and drain regions and the gate conductor define a fin field effect transistor (FinFET). The drift region is tapered, such that the drift region is wider closest to the undoped gate-control portion of the fin and thinner closest to the drain region of the fin.

According to another example, a non-transitory computer readable storage medium readable by a computerized device is disclosed. The non-transitory computer readable storage medium stores instructions executable by the computerized device to perform an isolation technique for bulk fin field effect transistors (FinFETs). According to the method, a bulk silicon wafer having a top surface and a bottom surface is provided. A conductive layer is formed on the top surface of the silicon wafer. A portion of the conductive layer is doped. An oxide layer is formed on the conductive layer. The conductive layer is between the silicon wafer and the oxide layer. The conductive layer comprises a well region. A fin structure extends through the oxide layer. The fin structure comprises an upper portion and a lower portion. The upper portion of the fin structure is undoped. A gate structure surrounds the upper portion of the fin structure. Source and drain regions are formed adjacent to the fin structure. The source and drain regions and the gate structure define a fin field effect transistor (FinFET). The lower portion of the fin structure comprises a sub-fin extending below the region surrounded by the gate structure. The sub-fin comprises an upper portion and a lower portion. The upper portion of the sub-fin is undoped. The lower portion of the sub-fin is doped. A portion of the well region of the conductive layer comprises part of the lower portion of the sub-fin.

### BRIEF DESCRIPTION OF THE DRAWINGS

The foregoing and other exemplary purposes, aspects, and advantages will be better understood from the following detailed description of exemplary devices and methods herein with reference to the drawings, in which:

FIG. 1A is a side view of a FinFET structure according to devices and methods herein;

FIG. 1B is a top view of a FinFET structure according to devices and methods herein;

FIGS. 2-15 are schematic diagrams of a sectional view of semiconductor structure in fabricating a FinFET structure according to devices and methods herein;

FIG. 16 is a flow diagram illustrating devices and methods herein;

FIG. 17 is a block diagram illustrating an exemplary design flow used, for example, in the logic design, simulation, test, layout, and manufacture of the structures disclosed herein; and

FIG. 18 is a schematic diagram illustrating an exemplary hardware system that can be used in the implementation of the design flow according to devices and methods herein.

### DETAILED DESCRIPTION

Referring now to the drawings, there are shown exemplary illustrations of the structures of an asymmetric lateral diffusion metal oxide semiconductor (LDMOS) fin field effect transistors (FinFET) in a semiconductor wafer and method of forming such structure.

For purposes herein, a “semiconductor” is a material or structure that may include an implanted impurity that allows the material to sometimes be a conductor and sometimes be an insulator, based on electron and hole carrier concentration. As used herein, “implantation processes” can take any appropriate form (whether now known or developed in the future) and can comprise, for example, ion implantation, etc.

Within a transistor, the semiconductor (or channel region) is positioned between a conductive “source” region and a similarly conductive “drain” region and when the semiconductor is in a conductive state, the semiconductor allows electrical current to flow between the source and drain. A “gate” is a conductive element that is electrically separated from the semiconductor by a “gate oxide” (which is an insulator). The current/voltage within the gate changes the conductivity of the channel region of the transistor.

A positive-type transistor “P-type transistor” uses impurities such as boron, aluminum or gallium, etc., within an intrinsic semiconductor substrate (to create deficiencies of valence electrons) as a semiconductor region. Similarly, an “N-type transistor” is a negative-type transistor that uses impurities such as antimony, arsenic or phosphorous, etc., within an intrinsic semiconductor substrate (to create excessive valence electrons) as a semiconductor region.

Generally, transistor structures are formed by depositing or implanting impurities into a substrate to form at least one semiconductor channel region, bordered by shallow trench isolation regions below the top (upper) surface of the substrate. A “substrate” herein can comprise any material appropriate for the given purpose (whether now known or developed in the future) and can comprise, for example, Si, SiC, SiGe, SiGeC, other III-V or II-VI compound semiconductors, or organic semiconductor structures, etc. The “shallow trench isolation” (STI) structures are well-known to those ordinarily skilled in the art and are generally formed by patterning openings/trenches within the substrate and growing or filling the openings with a highly insulating material (this allows different active areas of the substrate to be electrically isolated from one another).

According to devices and methods herein, a novel combination of elements can be used to enable an LDMOS FinFET. The structure described below provides a specific fin geometry shaping to lower the peak electric fields in the drift region at the drain of LDMOS FinFET devices.

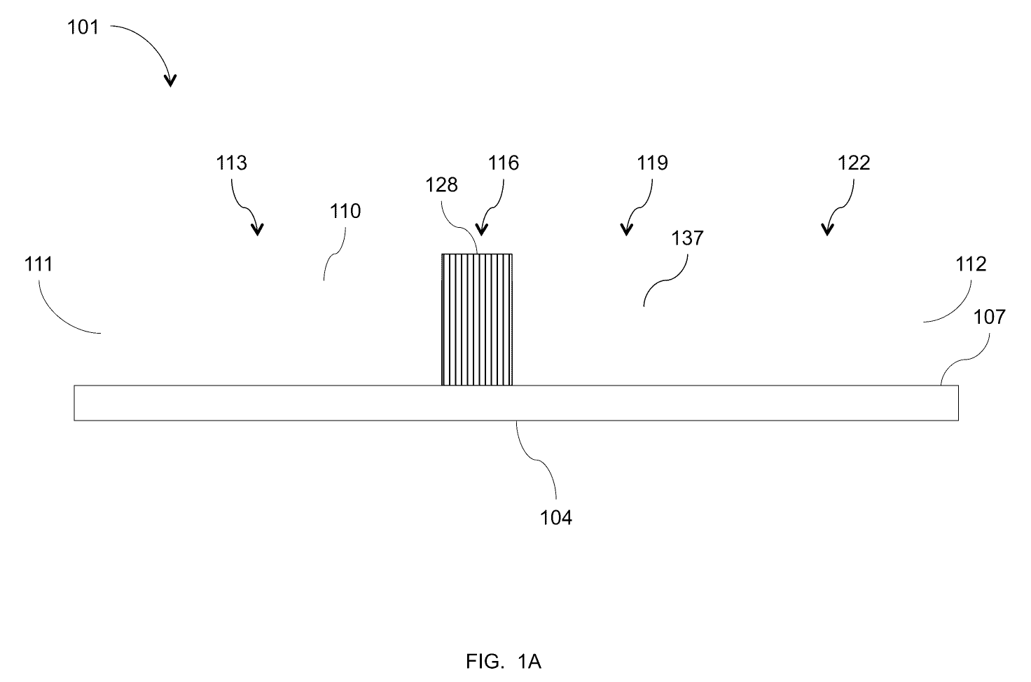

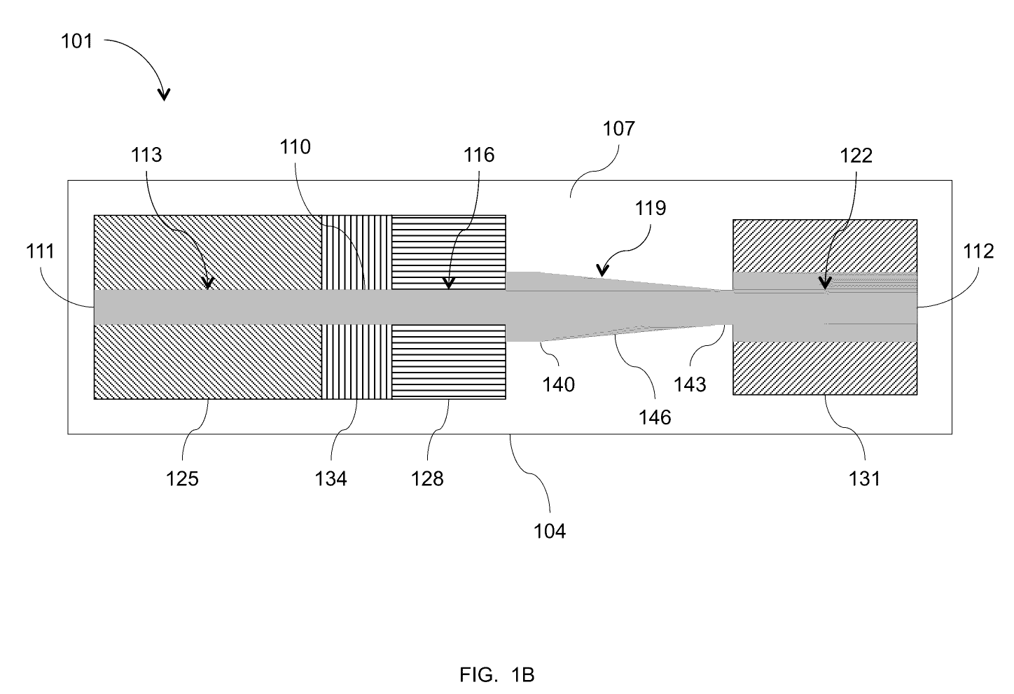

Referring to the drawings, FIGS. 1A and 1B show the structure of an asymmetric lateral diffusion metal oxide semiconductor (LDMOS) FinFET, indicated generally as 101. According to devices and methods herein, the FinFET 101 may be fabricated on a substrate 104 having a top surface 107. The FinFET 101 includes a fin 110 attached to the top surface 107 and in a vertical position relative to the top surface 107. The fin 110 has a first end 111 and a second end 112. As is known in the art, the fin 110 may be formed by depositing an undoped conductive layer on the substrate 104, planarizing the undoped conductive layer, and etching the undoped conductive layer to expose the fin 110. The fin 110 is segregated into multiple regions, such as a source region 113, a gate-control region 116, a drift region 119, and a drain region 122. As shown in FIG. 1B, the FinFET 101 also includes a source contact 125, a gate conductor 128, and a drain contact 131. The FinFET may also include one or more spacers 134. The source region 113 is heavily doped of a first polarity. By “doping” is meant intentionally introducing impurities, as described above, into a pure semiconductor for the purpose of modulating its electrical properties. The gate-control region 116 is between the source region 113 and the drift region 119 and is substantially undoped or very low doped. The drift region 119 is between the gate-control region 116 and the drain region 122, on the opposite side from the source region 113. The drift region 119 has light doping of the first polarity. In particular, the amount of doping of the source region 113 is significantly greater than the amount of doping of the drift region 119. The drain region 122 is next to the drift region 119 and is heavily doped of the first polarity. The gate conductor 128 is attached to the top surface 107 of the substrate 104 and located on at least two sides of the gate-control region 116. The portion of the fin 110 in the drift region 119 is tapered in geometry. A taper is a continual progressive change in the geometry of the fin 110. For example, as shown in FIG. 1A, the drift region 119 of the FinFET 101 may have the fin 110 tapered in height with maximum height substantially adjacent to the gate-control region 116. Height is measured from the top surface 107 of the substrate 104. For example, the vertical taper can have an edge 137 that has an angle relative to the plane of the top surface 107 of the substrate 104 (15°, 30°, 45°, etc.), as shown in FIG. 1A. Alternatively, or in addition, the drift region 119 may have the fin 110 tapered in width. As shown in FIG. 1B, the drift region 119 may be wider closest to the gate-control region 116 (as shown at 140) and thinner closest to the drain region 122 (as shown at 143). By width is meant in a direction parallel to the top surface 107 of the substrate 104. For example, the taper of the width is a continual progressive change in width from a first width (such as shown at 140) to a second width (such as shown at 143). That is, there is a relative change in the measure of the different widths (e.g., 25% less, 33% less, 50% less, etc.). Additionally, the taper can have an edge 146 that has an angle relative to the plane of the fin (15°, 30°, 45°, etc.).

According to structures and methods herein, the doping may be accomplished with a p-type impurity species, such as boron, to render it p-type in which holes are the majority carriers and dominate the electrical conductivity of the constituent semiconductor material. Alternatively, the doping may be accomplished with an n-type impurity species, such as arsenic to render it n-type in which electrons are the majority carriers and dominate the electrical conductivity of the semiconductor material.

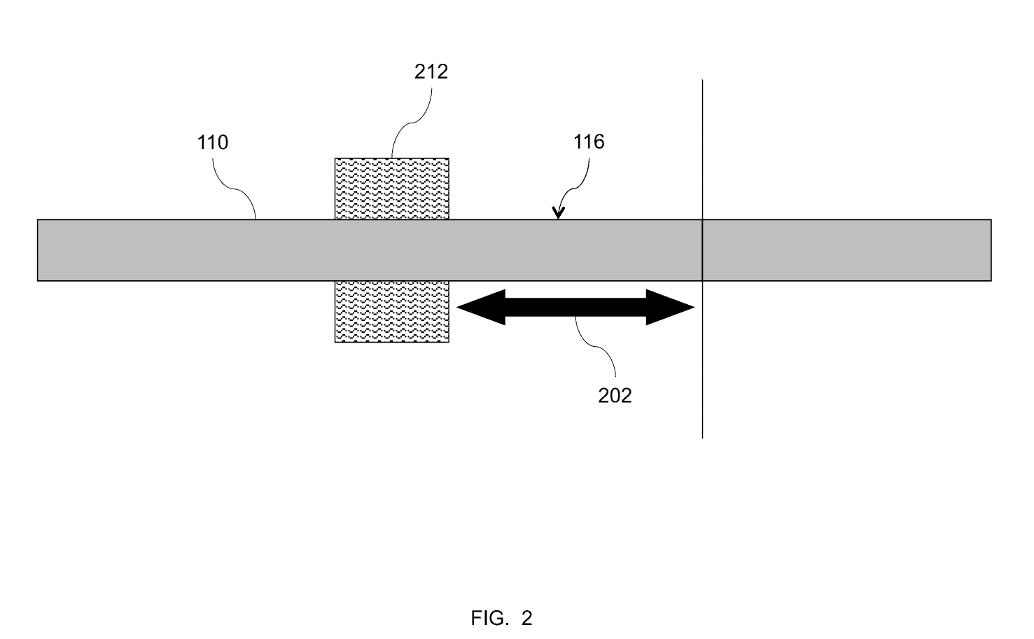

FIGS. 2-15 illustrate the processing steps in fabricating a FinFET structure according to devices and methods herein. The substrate 104 described above is omitted in FIGS. 2-15 to avoid clutter. Referring to FIG. 2, the drift region 119 may be approximately 50 nm-500 nm in length, as indicated by arrow 202. The fin 110 starts a little thicker than the final product shown in FIG. 1. In practice, the thickness of the fin 110 may begin approximately one-third the length of the drift region 119 and approximately 40 nm in height or greater. A ‘dummy’ gate 212 is formed offset from center for spacing, which may be approximately 20 nm-60 nm in length, or greater.

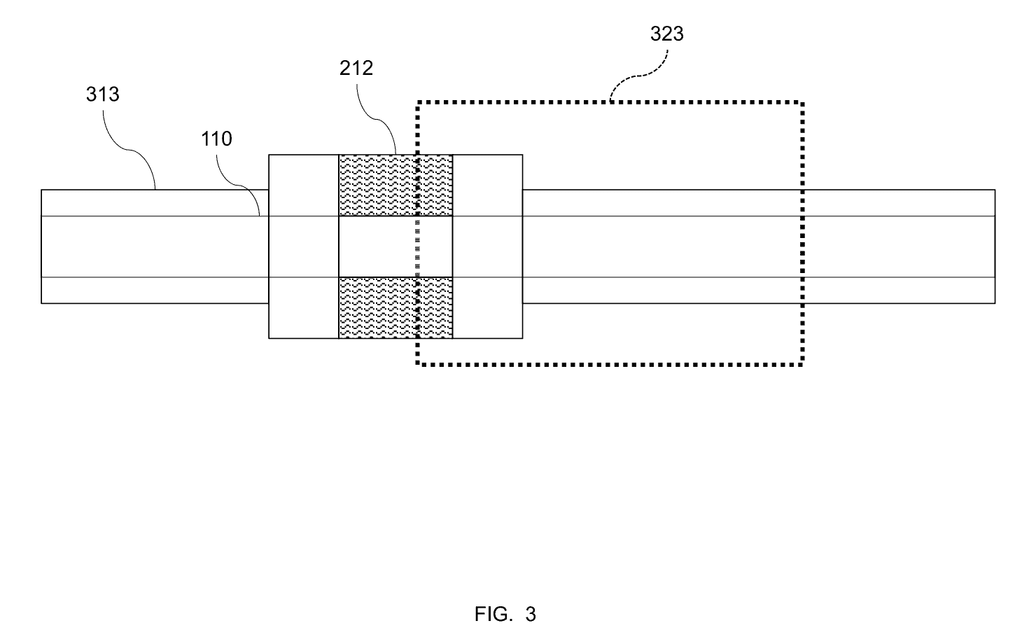

In FIG. 3, a spacer layer 313 is deposited over the fin 110 and dummy gate 212. A mask is provided to protect the bounded area 323 and etching is performed to expose portions of the fin 110. The etching may comprise reactive ion etch (RIE), although other material removal processes can be used. The mask protects portions of the structure while using a material removal process. A hardmask can be formed of any suitable material, whether now known or developed in the future, such as a metal or organic or inorganic (Si₃N₄, SiC, SiO₂C (diamond)) hardmask, that has etch resistance greater than the substrate and insulator materials used in the remainder of the structure.

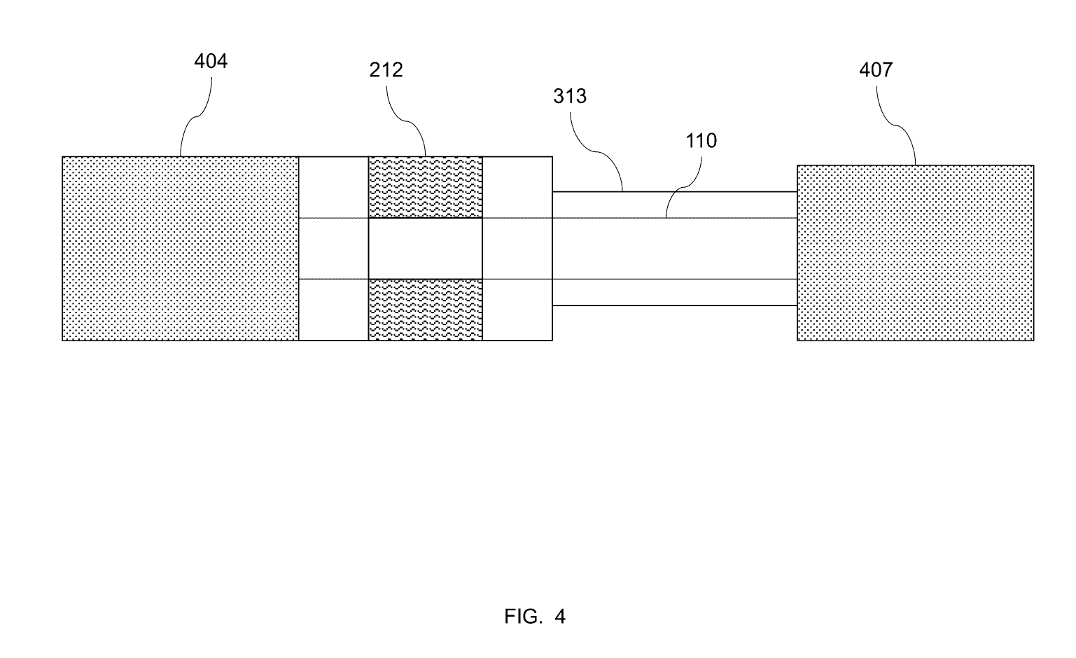

In FIG. 4, sections of silicon (or poly) are epitaxially grown where the fin 110 is exposed, as indicated at 404 and 407.

When patterning any material herein, the material to be patterned can be grown or deposited in any known manner and a patterning layer (such as an organic photoresist) can be formed over the material. The patterning layer (resist) can be exposed to some pattern of light radiation (e.g., patterned exposure, laser exposure, etc.) provided in a light exposure pattern, and then the resist is developed using a chemical agent. This process changes the physical characteristics of the portion of the resist that was exposed to the light. Then one portion of the resist can be rinsed off, leaving the other portion of the resist to protect the material to be patterned. A material removal process is then performed (e.g., plasma etching, etc.) to remove the unprotected portions of the material to be patterned. The resist is subsequently removed to leave the underlying material patterned according to the light exposure pattern.

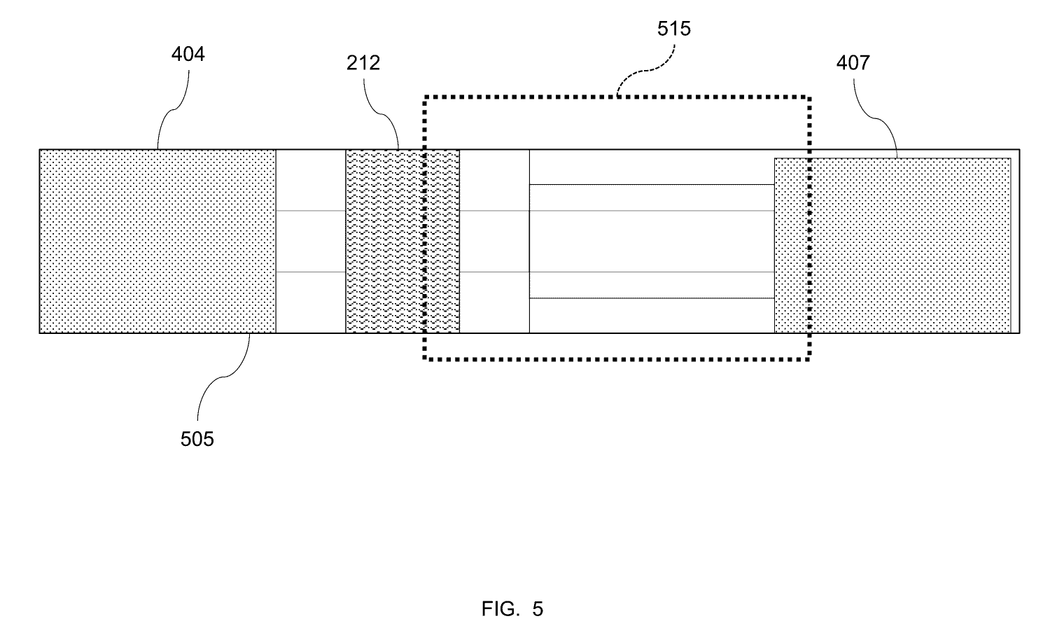

In FIG. 5, a nitride layer 505 is deposited as a mask to protect portions of the structure. In this instance, the bounded area 515 remains unprotected for etching, such as RIE. The bounded area 515 may overlap to approximately the middle of the dummy gate 212 and a portion of the epitaxially grown silicon section 407. The tolerance for overlay is approximately 7-10 nm.

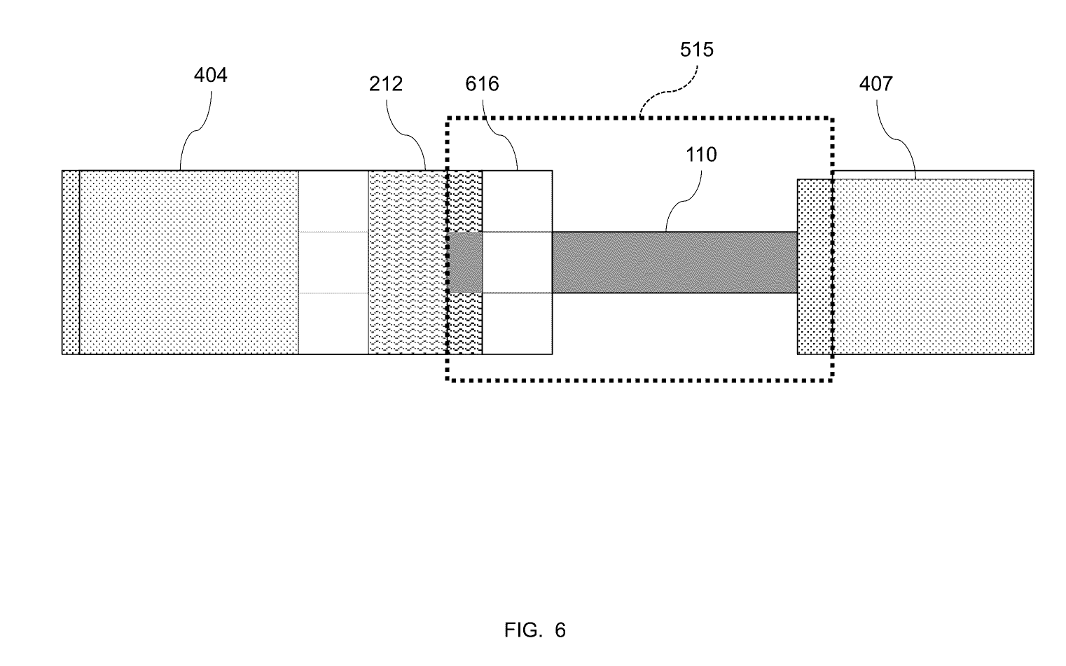

As shown in FIG. 6, the bounded area 515 is open and a spacer 616 is formed next to the dummy gate 212. At this stage of the process, the epitaxially grown silicon sections 404, 407 may be doped by implanting an appropriate impurity. Depending on the anticipated use of the FinFET 101, the doped sections may be either p-doped or n-doped.

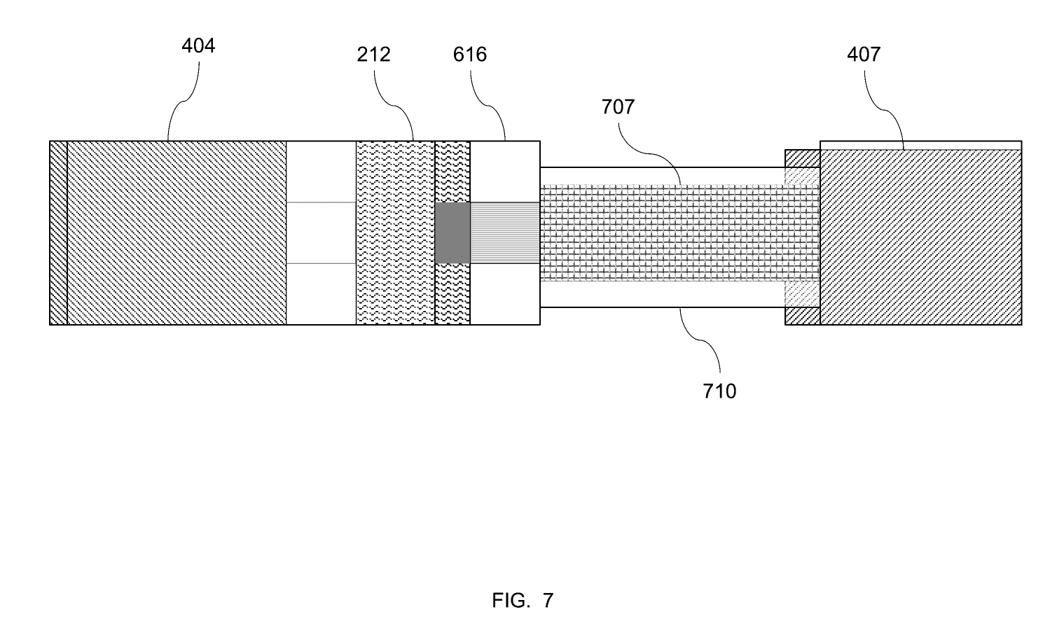

In FIG. 7, an oxide layer 707 is deposited in contact with the silicon on the previously exposed region on top of the fin 110. Another nitride layer 710 is deposited over the oxide layer 707.

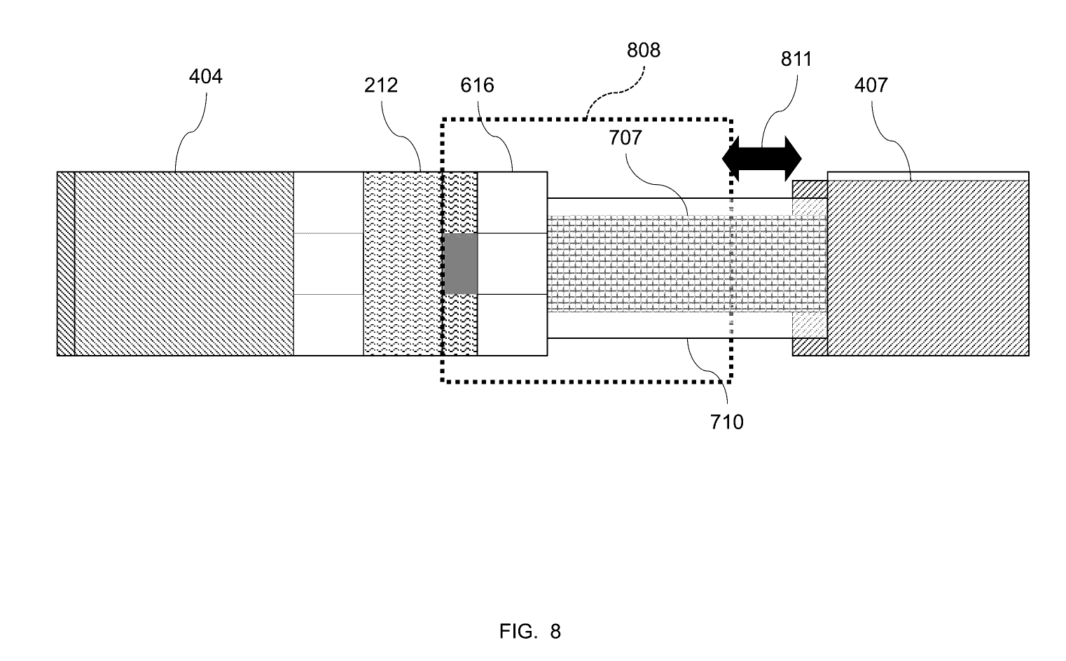

In FIG. 8, an additional masked etching process is performed. The mask, indicated by bounded area 808, is offset from the edge of the epitaxially grown silicon section 407 by a sufficient distance, as indicated by arrow 811, to expose a portion of the fin 110. Other regions of the structure remain protected.

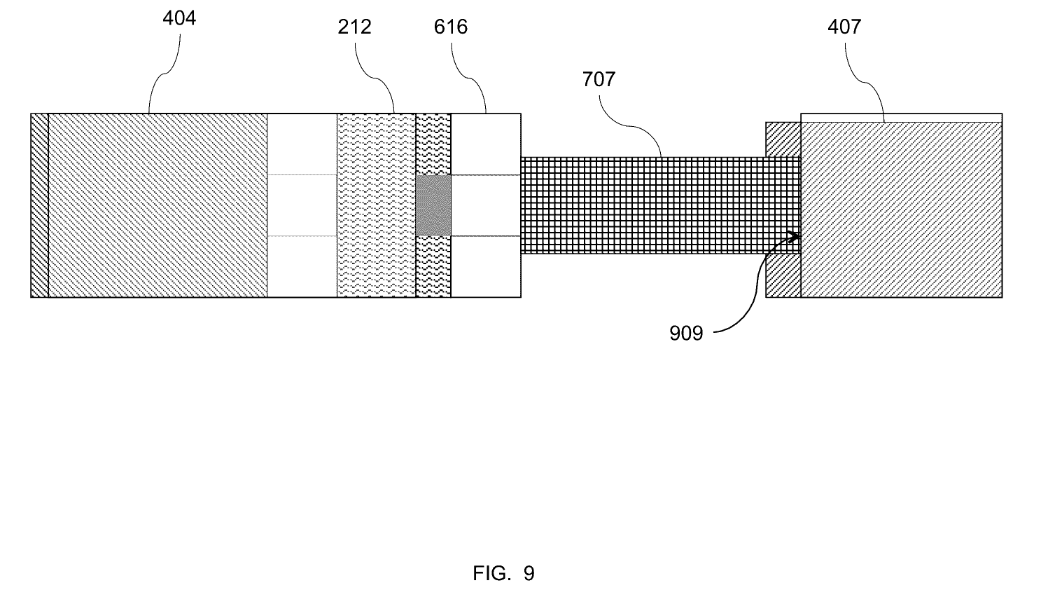

Referring to FIG. 9, LOCOS oxidation occurs due to the oxide layer 707. LOCOS, short for LOCal Oxidation of Silicon, is a process where silicon dioxide is formed in selected areas on a silicon wafer having the Si—SiO₂ interface at a lower point than the rest of the silicon surface. The LOCOS process utilizes the different rates of oxidation of silicon and silicon nitride, which is used for masking by the nitride layer 710. The silicon nitride masks the region where no oxidation should occur, the oxide only grows on the bare silicon. Since silicon and silicon nitride have different coefficients of thermal expansion, the oxide layer 707 is deposited between the silicon and the silicon nitride to prevent strain due to temperature changes. While the oxidation on the bare silicon takes place, the oxide in the oxide layer 707 causes a lateral diffusion of oxide beneath the nitride layer 710 and thus a slight growth of oxide at the edge of the nitride layer 710. This extension has the shape of a bird's beak whose length depends on the length of the oxidation process and the thickness of the oxide layer 707 and the nitride layer 710, as well. In other words, when performing LOCOS steps for thermal oxidation growth, a “bird's beak” effect is commonplace. As the oxide grows, the nitride mask, which is meant to block the oxide from growing everywhere, is slightly bent due to stress caused by the oxide pushing the nitride as it grows. The LOCOS will “birds beak” from the right edge of the oxide layer 707, indicated at 909, and cause the fin 110 to taper from the right edge 909. The tapered portion comprises the drift region 119 of the FinFET 101 with the fin 110 having maximum width substantially adjacent to the gate-control region 116.

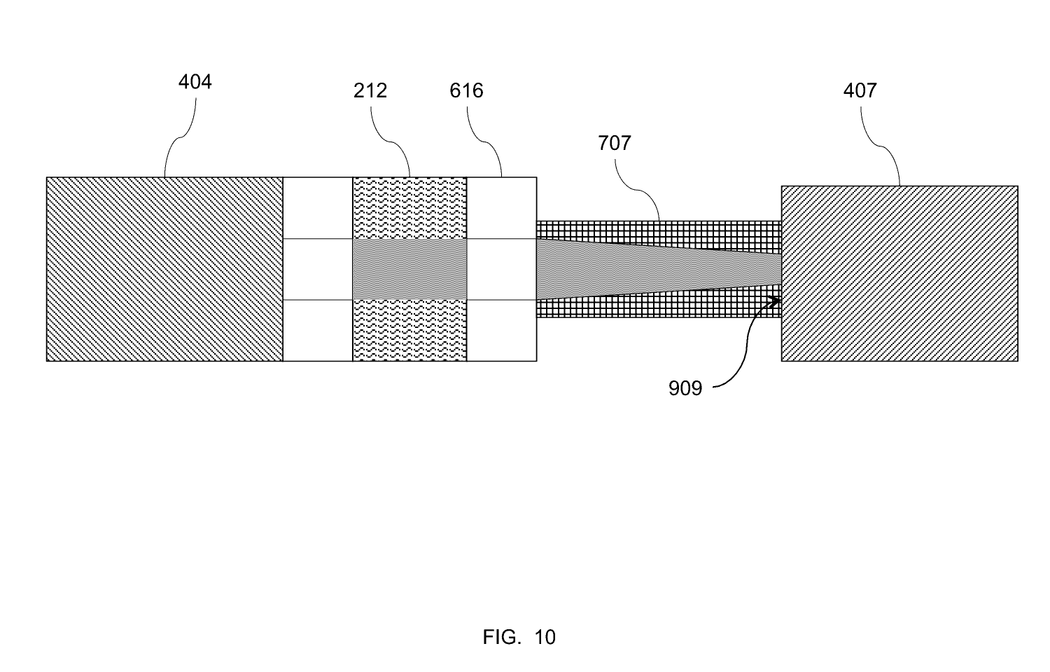

In FIG. 10, the oxide layer 707 and nitride layer 710 may be removed from the other regions of the structure by an appropriate material removal process. In some cases, the oxide layer 707 need not be removed from the LOCOS region.

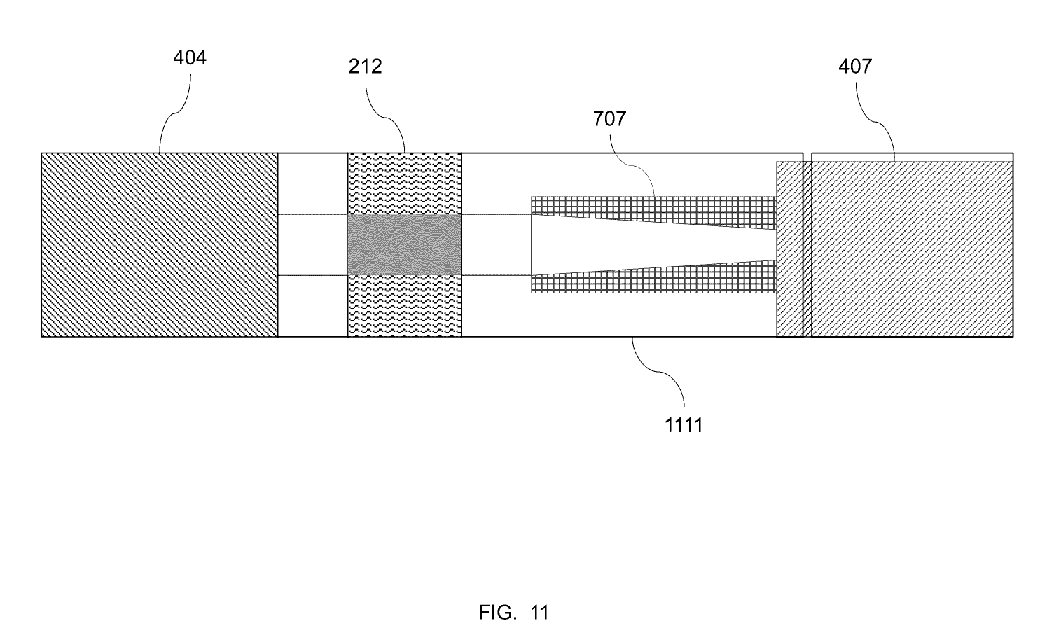

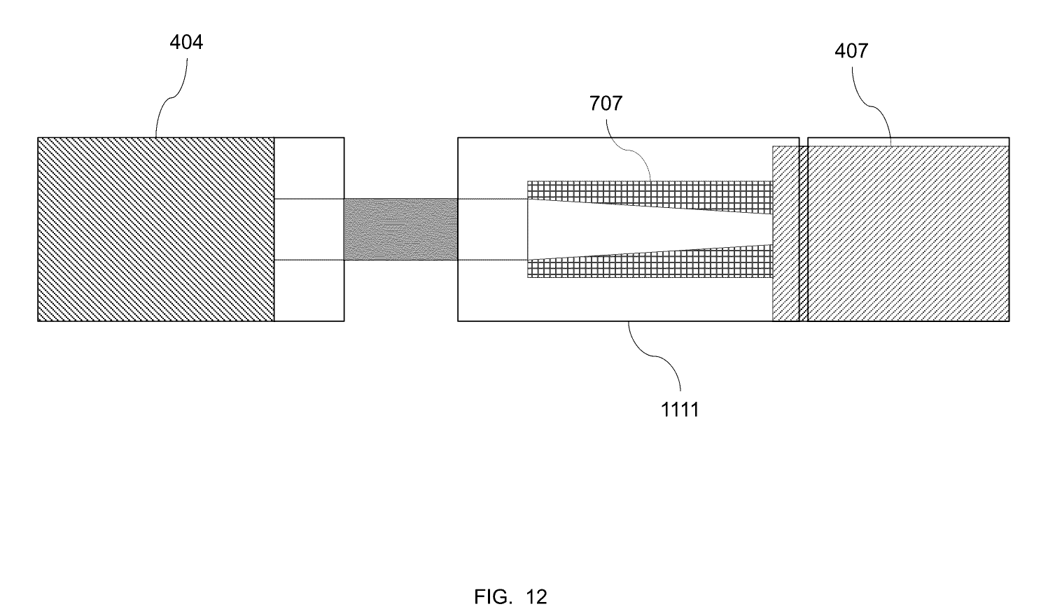

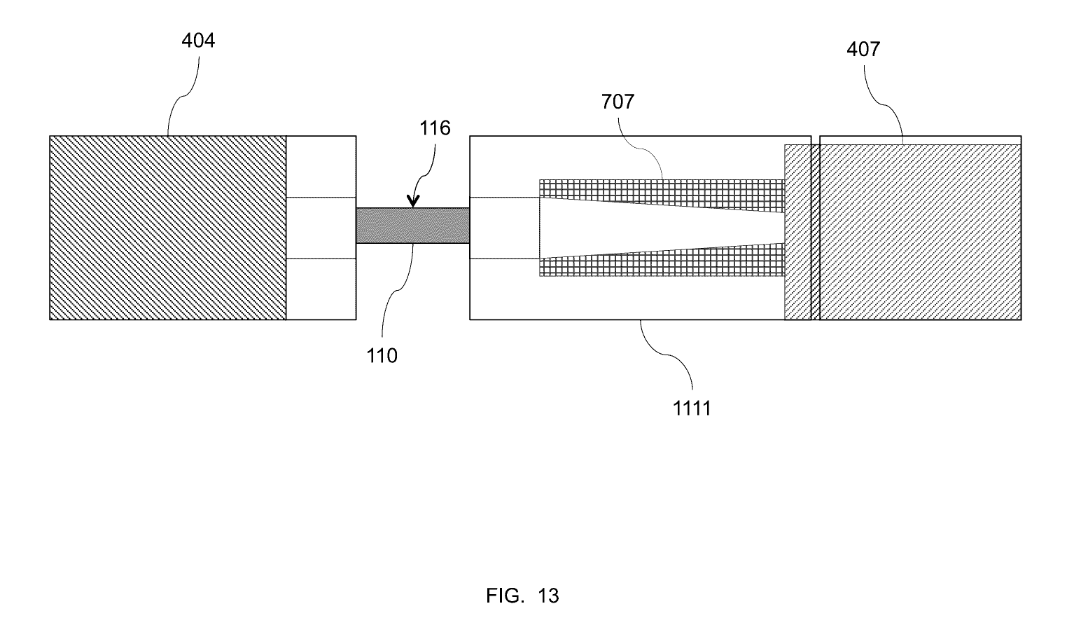

In FIG. 11, another nitride mask 1111 is applied over the LOCOS region so that the dummy gate 212 can be removed, as shown in FIG. 12. Optionally, the fin 110 may be thinned in the gate-control region 116 by an appropriate process, as shown in FIG. 13.

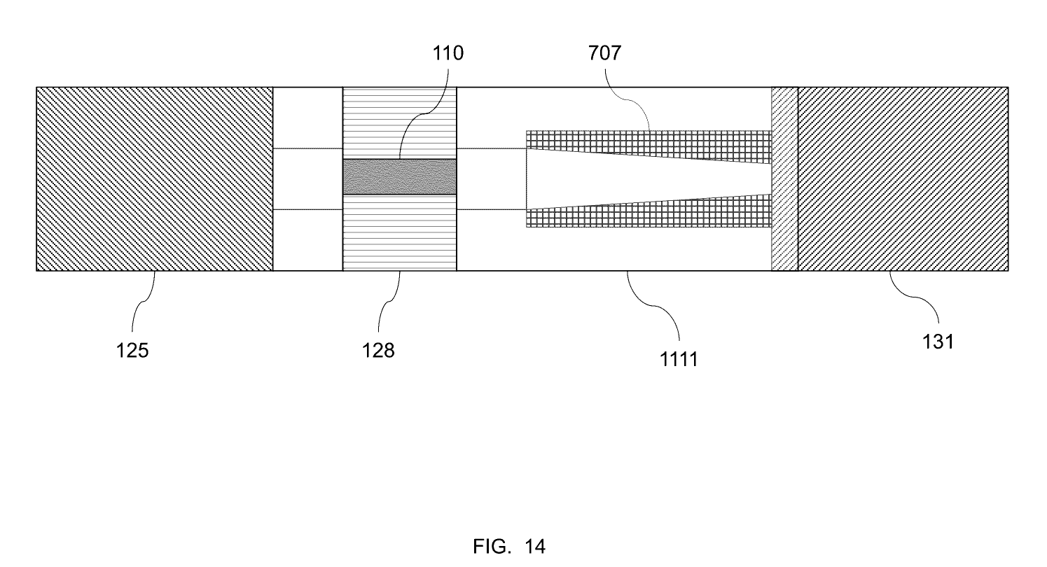

In FIG. 14, the gate conductor 128 (sometimes called a gate stack) is formed surrounding the thinned portion of the fin 110. The source and drain contacts 125, 131 and the gate conductor 128 constitute the three main connection points for the fin field effect transistors (FinFET), indicated generally as 101, in FIG. 1.

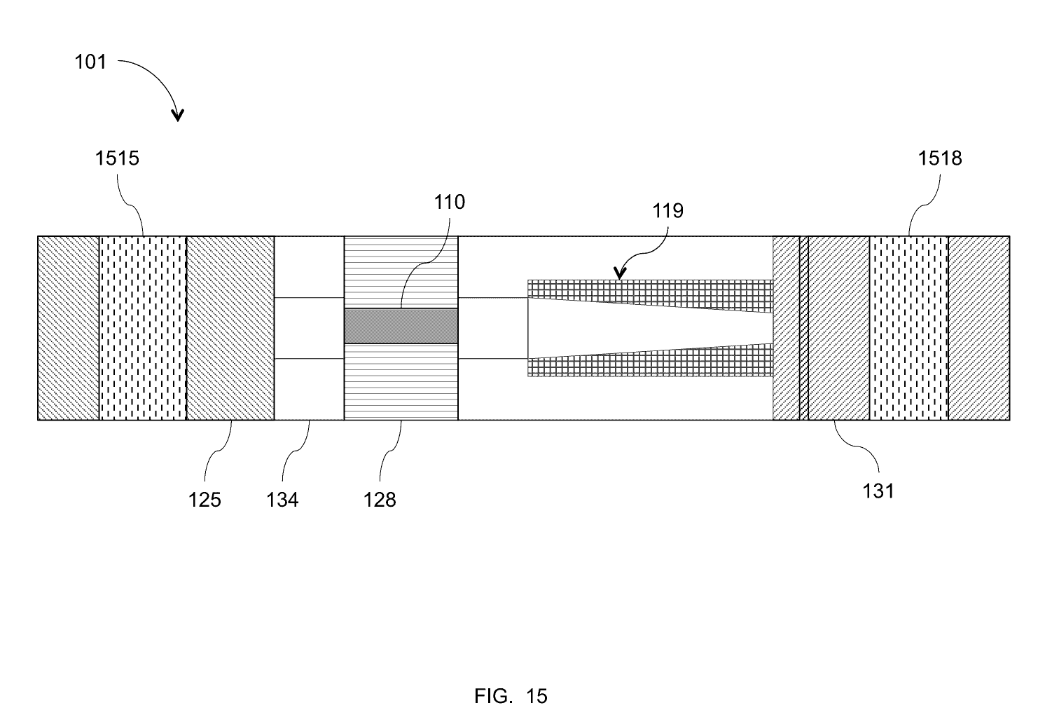

As shown in FIG. 15, isolation trenches 1515 and 1518 may be formed to isolate the FinFET 101. The isolation trenches 1515 and 1518 may be filled with a silicide. The source contact 125, spacer 134, drain contact 131, and drift region 119 may be covered with a nitride fill.

The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, any alloys of such metals, and may be deposited using physical vapor deposition, chemical vapor deposition, or any other technique known in the art.

The structure described herein enables a unique asymmetric lateral diffusion metal oxide semiconductor (LDMOS) FinFET. As described above, the doped region of the FinFET 101 may be either p-doped or n-doped. Both the source region 113 and drain region 122 have very high doping and the drift region 119 has light doping. Furthermore, the source region 113, drain region 122, and drift region 119 all have the same type of doping. The gate-control region 116 has very low or no doping. Accordingly, the technique described herein can be constructed in n-type and p-type versions of the FinFET 101, each with appropriate doping and electrical potentials in order to support desired performance.

It is anticipated that the asymmetric drain region can drop about 5V/50 nm length, concentrated at the drain edge. Therefore, for a 5V tolerant device:
start with a fin approximately 16 nm wide
form a drift region approximately 50 nm in length
the gate length may be approximately 20 nm-60 nm.

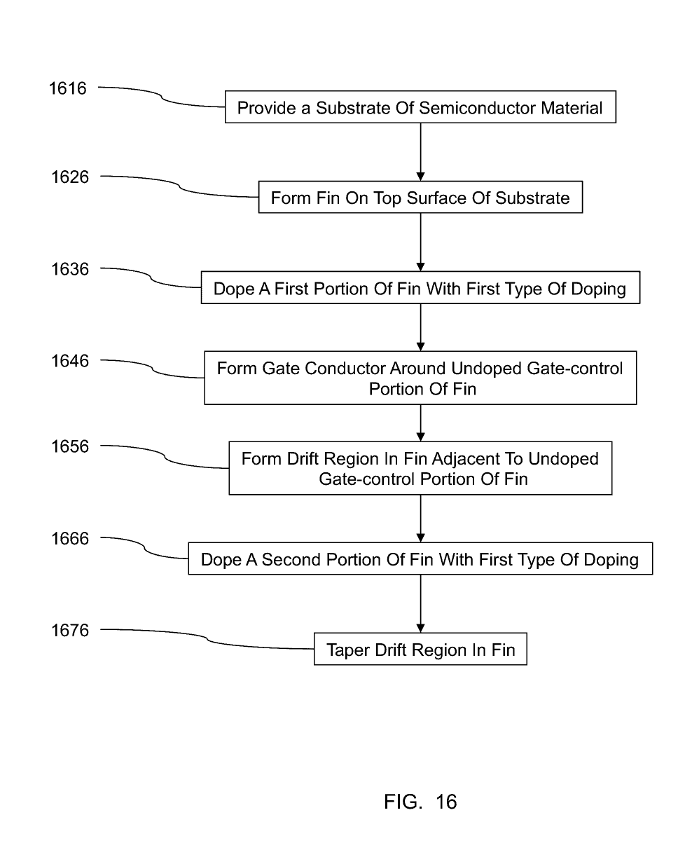

FIG. 16 illustrates a logic flowchart for fabricating a high voltage FinFET structure with a shaped drift region, according to devices and methods herein. At 1616, a substrate of semiconductor material is provided. The substrate has a top surface. At 1626, a fin is formed on the substrate. This fin has a height above the top surface of the substrate. At 1636, a first portion of the fin is doped with a first type of doping. The first portion of the fin comprises a source region. A gate conductor is formed on the substrate, at 1646. The gate conductor is formed around an undoped gate-control portion of the fin, adjacent to the source region. At 1656, a drift region is formed in the fin, adjacent to the undoped gate-control portion of the fin and opposing the source region. The drift region has the first type of doping, the source region being more heavily doped relative to the drift region. At 1666, a second portion of the fin, adjacent to the drift region, is doped with the first type of doping. The second portion of the fin comprises a drain region. The source and drain regions and the gate conductor define a fin field effect transistor (FinFET). At 1676, the drift region is tapered, such that the drift region is wider closest to the undoped gate-control portion of the fin and thinner closest to the drain region of the fin.

According to exemplary lateral diffusion metal oxide semiconductor (LDMOS) FinFET devices described herein, a FinFET 101 includes a substrate 104 having a top surface 107 with a fin 110 attached to the top surface 107. The fin 110 is substantially vertical and includes multiple regions such as: a source region 113 having doping of a first polarity, an undoped gate-control region 116 adjacent to the source region 113, a drift region 119 adjacent to the undoped gate-control region 116 and opposing the source region 113, and a drain region 122. The drift region 119 has doping of the first polarity. The amount of doping of the source region 113 is greater than the amount of doping of the drift region 119. The drain region 122 is next to the drift region 119 and the drain region 122 has doping of the first polarity. The drift region 119 comprises a fin 110, tapered in geometry, being wider closest to the undoped gate-control region 116 and thinner closest to the drain region 122. The FinFET 101 also includes a gate conductor 128 attached to the top surface 107 of the substrate 104 and located on at least two sides of the undoped gate-control region 116.

With its unique and novel features, the devices and methods herein teach a semiconductor device including a substrate 104, which may comprise a semiconductor substrate. This substrate 104 has isolation trenches 1515, 1518 in the top surface 107 of the substrate 104, and a fin 110. The structure of the fin 110 is perpendicular to the substrate 104 and bounded by the structure of the isolation trenches 1515, 1518. The fin 110 comprises, a source region 113 having a first type of doping, an undoped gate-control region 116 adjacent to the source region 113, a drift region 119 adjacent to the undoped gate-control region 116 and opposing the source region 113, and a drain region 122 adjacent to the drift region 119. The drift region 119 has the first type of doping, with the source region 113 being more heavily doped relative to the drift region 119. The drift region 119 is wider closer to the undoped gate-control region 116 and thinner closer to the drain region 122. The drain region 122 also has the first type of doping. The devices and methods include a gate conductor 128 over the substrate 104, relative to the top surface 107. This gate conductor 128 is adjacent to the undoped gate-control region 116.

While only one or a limited number of transistors are illustrated in the drawings, those ordinarily skilled in the art would understand that many different types transistor could be simultaneously formed with the embodiment herein and the drawings are intended to show simultaneous formation of multiple different types of transistors; however, the drawings have been simplified to only show a limited number of transistors for clarity and to allow the reader to more easily recognize the different features illustrated. This is not intended to limit this disclosure because, as would be understood by those ordinarily skilled in the art, this disclosure is applicable to structures that include many of each type of transistor shown in the drawings.

The methods as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

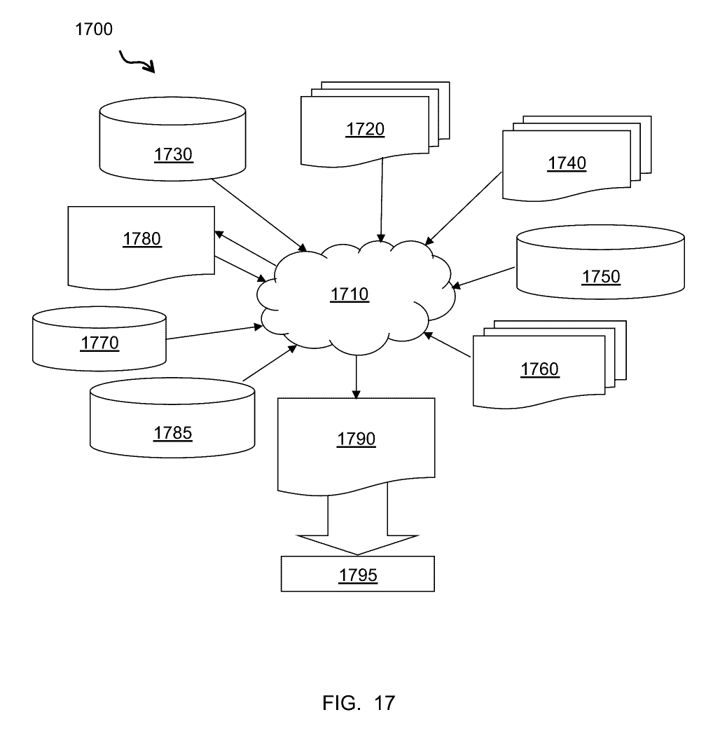

FIG. 17 shows a block diagram of an exemplary design flow 1700 used for example, in semiconductor IC logic design, simulation, test, layout, and manufacture. Design flow 1700 includes processes, machines, and/or mechanisms for processing design structures or devices to generate logically or otherwise functionally equivalent representations of the design structures and/or devices described above and shown in FIGS. 1-15. The design structures processed and/or generated by design flow 1700 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 1700 may vary depending on the type of representation being designed. For example, a design flow 1700 for building an application specific IC (ASIC) may differ from a design flow 1700 for designing a standard component or from a design flow 1700 for instantiating the design into a programmable array, for example a programmable gate array (PGA) or a field programmable gate array (FPGA) offered by Altera® Inc. or Xilinx® Inc.

FIG. 17 illustrates multiple such design structures including an input design structure 1720 that is preferably processed by a design process 1710. Design structure 1720 may be a logical simulation design structure generated and processed by design process 1710 to produce a logically equivalent functional representation of a hardware device. Design structure 1720 may also or alternatively comprise data and/or program instructions that when processed by design process 1710, generate a functional representation of the physical structure of a hardware device. Whether representing functional and/or structural design features, design structure 1720 may be generated using electronic computer-aided design (ECAD) such as implemented by a core developer/designer. When encoded on a machine-readable data transmission, gate array, or storage medium, design structure 1720 may be accessed and processed by one or more hardware and/or software modules within design process 1710 to simulate or otherwise functionally represent an electronic component, circuit, electronic or logic module, apparatus, device, or system such as those shown in FIGS. 1-15. As such, design structure 1720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher-level design languages such as C or C++.

Design process 1710 preferably employs and incorporates hardware and/or software modules for synthesizing, translating, or otherwise processing a design/simulation functional equivalent of the components, circuits, devices, or logic structures shown in FIGS. 1-15 to generate a Netlist 1780 which may contain design structures such as design structure 1720. Netlist 1780 may comprise, for example, compiled or otherwise processed data structures representing a list of wires, discrete components, logic gates, control circuits, I/O devices, models, etc. that describes the connections to other elements and circuits in an integrated circuit design. Netlist 1780 may be synthesized using an iterative process in which Netlist 1780 is resynthesized one or more times depending on design specifications and parameters for the device. As with other design structure types described herein, Netlist 1780 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 1710 may include hardware and software modules for processing a variety of input data structure types including Netlist 1780. Such data structure types may reside, for example, within library elements 1730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 1740, characterization data 1750, verification data 1760, design rules 1770, and test data files 1785 which may include input test patterns, output test results, and other testing information. Design process 1710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 1710 without deviating from the scope and spirit of the invention. Design process 1710 may also include modules for performing standard circuit design processes such as timing analysis, verification, design rule checking, place and route operations, etc.

Design process 1710 employs and incorporates logic and physical design tools such as HDL compilers and simulation model build tools to process design structure 1720 together with some or all of the depicted supporting data structures along with any additional mechanical design or data (if applicable), to generate a second design structure 1790. Design structure 1790 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 1720, design structure 1790 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-15. In one embodiment, design structure 1790 may comprise a compiled, executable HDL simulation model that functionally simulates the devices shown in FIGS. 1-15.

Design structure 1790 may also employ a data format used for the exchange of layout data of integrated circuits and/or symbolic data format (e.g. information stored in a GDSII (GDS2), GL1, OASIS, map files, or any other suitable format for storing such design data structures). Design structure 1790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-15. Design structure 1790 may then proceed to a stage 1795 where, for example, design structure 1790: proceeds to tape-out, is released to manufacturing, is released to a mask house, is sent to another design house, is sent back to the customer, etc.

Aspects of the present disclosure are described herein with reference to flowchart illustrations and/or block diagrams of methods, apparatus (systems), and computer program products according to devices and methods herein. It will be understood that each block of the flowchart illustrations and/or two-dimensional block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

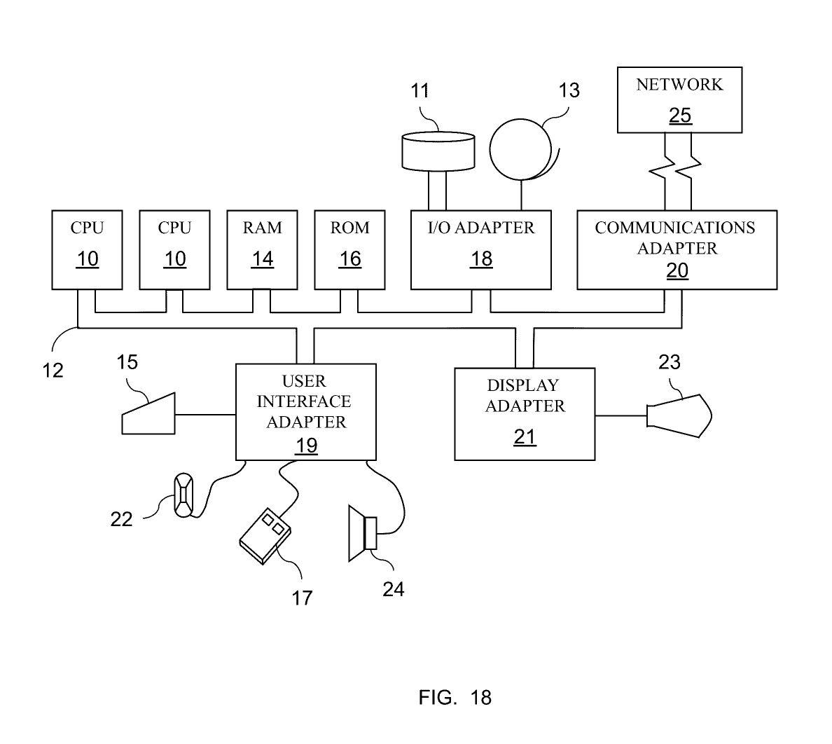

A representative hardware environment for implementing the devices and methods herein is depicted in FIG. 18. This schematic drawing illustrates a hardware configuration of an information handling/computer system in accordance with the devices and methods herein. The system comprises at least one processor or central processing unit (CPU) 10. The CPUs 10 are interconnected via system bus 12 to various devices such as a Random Access Memory (RAM) 14, Read Only Memory (ROM) 16, and an Input/Output (I/O) adapter 18. The I/O adapter 18 can connect to peripheral devices, such as disk units 11 and tape drives 13, or other program storage devices that are readable by the system. The system can read the instructions on the program storage devices and follow these instructions to execute the methodology of the devices and methods herein.

In FIG. 18, CPUs 10 perform various processing based on a program stored in a Read Only Memory (ROM) 16 or a program loaded from a peripheral device, such as disk units 11 and tape drives 13 to a Random Access Memory (RAM) 14. In the RAM 14, required data when the CPU 10 performs the various processing or the like is also stored as necessary. The CPU 10, the ROM 16, and the RAM 14 are connected to one another via a bus 12. An input/output adapter 18 is also connected to the bus 12 to provide an input/output interface, as necessary. A removable medium, such as a magnetic disk, an optical disk, a magneto-optical disk, a semiconductor memory, or the like, is installed on the peripheral device, as necessary, so that a computer program read therefrom may be installed into the RAM 14, as necessary.

The system further includes a user interface adapter 19 that connects a keyboard 15, mouse 17, speaker 24, microphone 22, and/or other user interface devices such as a touch screen device (not shown) to the bus 12 to gather user input. Additionally, a communication adapter 20 including a network interface card such as a LAN card, a modem, or the like connects the bus 12 to a data processing network 25. The communication adapter 20 performs communication processing via a network such as the Internet. A display adapter 21 connects the bus 12 to a display device 23, which may be embodied as an output device such as a monitor (such as a Cathode Ray Tube (CRT), a Liquid Crystal Display (LCD), or the like), printer, or transmitter, for example.

The flowchart and block diagrams in the Figures illustrate the architecture, functionality, and operation of possible implementations of systems, methods, and computer program products according to various examples disclosed herein. In this regard, each block in the flowchart or block diagrams may represent a module, segment, or portion of code, which comprises one or more executable instructions for implementing the specified logical function(s). It should also be noted that, in some alternative implementations, the functions noted in the block might occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It should be understood that the terminology used herein is for the purpose of describing particular examples of the disclosed structures and methods and is not intended to be limiting of this disclosure. For example, as used herein, the singular forms “a”, “an”, and “the” are intended to include the plural forms as well, unless the context clearly indicates otherwise. Additionally, as used herein, the terms “comprises,” “comprising,” and/or “including,” when used in this specification, specify the presence of stated features, integers, steps, operations, elements, and/or components, but do not preclude the presence or addition of one or more other features, integers, steps, operations, elements, components, and/or groups thereof.

Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are understood to be relative locations as they are oriented and illustrated in the drawings (unless otherwise indicated). Terms such as “touching”, “on”, “in direct contact”, “abutting”, “directly adjacent to”, etc., are intended to indicate that at least one element physically contacts another element (without other elements separating the described elements).

The corresponding structures, materials, acts, and equivalents of all means or step plus function elements in the claims below are intended to include any structure, material, or act for performing the function in combination with other claimed elements as specifically claimed. The descriptions of the various examples of the present disclosure have been presented for purposes of illustration, but are not intended to be exhaustive or limited to the devices and methods disclosed. Many modifications and variations will be apparent to those of ordinary skill in the art without departing from the scope and spirit of the described examples. The terminology used herein was chosen to best explain the principles of the disclosed devices and methods, the practical application or technical improvement over technologies found in the marketplace, or to enable others of ordinary skill in the art to understand the devices and methods disclosed herein.

While various examples are described herein, it will be appreciated from the specification that various combinations of elements, variations, or improvements therein may be made by those skilled in the art, and are within the scope of the disclosure. In addition, many modifications may be made to adapt a particular situation or material to the teachings of the disclosed concepts without departing from the essential scope thereof. Therefore, it is intended that the concepts not be limited to the particular examples disclosed as the best mode contemplated for carrying out the devices and methods herein, but that the devices and methods will include all features falling within the scope of the appended claims.

1-12. (canceled)

13. A method comprising:
providing a substrate of semiconductor material, said substrate having a top surface;
forming a fin on said substrate, said fin having a height above said top surface of said substrate;
doping a first portion of said fin with a first type of doping, said first portion of said fin comprising a source region;
forming a gate conductor on said substrate, said gate conductor being formed around an undoped gate-control portion of said fin adjacent to said source region;
forming a drift region in said fin adjacent to said undoped gate-control portion of said fin, said undoped gate-control portion of said fin being between said source region and said drift region, said drift region having said first type of doping, said source region being more heavily doped relative to said drift region;
doping a second portion of said fin adjacent to said drift region with said first type of doping, said second portion of said fin comprising a drain region, said drift region being between said undoped gate-control portion of said fin and said drain region; and
tapering said drift region, said drift region having a first width close to said undoped gate-control portion of said fin and a second width close to said drain region, said second width being less than said first width.

14. The method according to claim 13, said forming said fin on said substrate further comprising:
depositing an undoped conductive layer on said substrate;
planarizing said undoped conductive layer; and
etching said undoped conductive layer to expose said fin.

15. The method according to claim 13, said tapering said drift region further comprising:
depositing an oxide layer on said fin between said undoped gate-control portion of said fin and said drain region; and
depositing a nitride layer on said oxide layer.

16. The method according to claim 13, said drift region being tapered in height, said fin being taller, relative to said top surface, closest to said undoped gate-control portion of said fin and shorter, relative to said top surface, closest to said drain region.

17. The method according to claim 13, further comprising:
forming a trench isolation structure in said top surface of said substrate, said fin being bounded by said trench isolation structure.

18. The method according to claim 13, further comprising:
doping n-type versions of said fin; and
doping p-type versions of said fin.

19. The method according to claim 13, further comprising:
applying a mask to a portion of said fin, said mask protecting said undoped gate-control portion of said fin and said drift region; and
epitaxially growing silicon sections in said source region and said drain region.

20. The method according to claim 13, further comprising:
applying contacts to said source region, said drain region, and said gate conductor.
